(19) United States
(12) Patent Application Publication
(10) Pub. No.: US 2019/0245006 A1
(43) Pub. Date: Aug. 8, 2019

(54) MICRO LED DISPLAY DEVICE

(71) Applicant: YingLight Technology Co. Ltd., Changhua County (TW)

(72) Inventors: PING-YU TSAI, Yunlin (TW); CHUNG-CHING CHEN, Pingtung County (TW)

(21) Appl. No.: 16/136,233

(22) Filed: Sep. 19, 2018

(30) Foreign Application Priority Data
Feb. 2, 2018 (TW) 107103892

(51) Int. Cl. H01L 27/15; H01L 33/50

(52) U.S. Cl. CPC H01L 27/156; G02B 5/201; H01L 33/507

(57) ABSTRACT

A micro LED display device includes a micro LED array, a light transmission layer, a color filter and a polarizer. The micro LED array includes a plurality of micro LEDs. The light transmission layer is located above the micro LED array. The color filter is located above the light transmission layer. The polarizer is located above the color filter.

### RELATED APPLICATIONS

This application claims priority to TW Application Serial Number 107103892, filed Feb. 2, 2018, which is herein incorporated by reference.

### BACKGROUND

### Technical Field

The present disclosure relates to a display device. More particularly, the present disclosure relates to a micro LED display device.

### Description of Related Art

Recently, a display device has been rapidly developed as an important human-machine interface. A portable electronic device, a computer or a television can represent complicated messages through the display device.

Owing to the demands on the large visible area, compact volume and low energy consumption, a liquid crystal display (LCD) device is getting more popular and has become a mainstream. A conventional LCD device 100 is shown in FIG. 1. The LCD device 100 includes, from bottom to top, a backlight module 111, a first polarizer 112, a first substrate 113, a transistor layer 114, a first electrode 115, a liquid crystal layer 116, a second electrode 117, a color filter 118, a second substrate 119 and a second polarizer 120. The operation mechanism of the LCD device 100 is then briefly described. The liquid crystal molecules in the liquid crystal layer 116 are twisted when a voltage is applied. One or more transistors in the transistor layer 114 is/are used to control the twisted direction of the liquid crystal molecules and are functioned as a light switch. Furthermore, lights emitted from the backlight module 111 are passed through the first polarizer 112 and the second polarizer 120 for generating different polarized direction lights to incorporate with the twisted directions of the liquid crystal molecules to control the brightness variation to form a gray scale. For generating color lights, a plurality of sub-pixel units 118a are disposed on the color filter 118, and a single pixel is constructed by combining a sub-pixel unit 118a corresponded to a red light color, a sub-pixel unit 118a corresponded to a green light color and a sub-pixel unit 118a corresponded to a blue light color. Therefore, an image with a full color can be formed by combining a plurality of pixels. Furthermore, an alignment film can be disposed on the first substrate 113 and the second substrate 119 for aligning the liquid crystal molecules. A voltage can be applied to the transistor layer 114 through the first electrode layer 115 and the second electrode 117.

However, the power efficiency and the brightness (contrast) of such kind of LCD device 100 is low because only few lights emitted from the backlight module 111 can pass through the liquid crystal layer 116. Furthermore, the manufacturing processes of the transistor layer 114 are complicated thereby increasing the manufacturing cost. A kind of OLED device has been reached to the market as an alternative of the LCD device 100. Although the OLED device has larger viewing angle then the conventional LCD device 100, however, issues such as light color flashing and light color decay still exist and will cause a short lifetime.

Therefore, there is a need to develop a display device having high power efficiency, large viewing angle and long lifetime.

### SUMMARY

According to one aspect of the present disclosure, a micro LED display device is provided. The micro LED display device includes a micro LED array, a light transmission layer, a color filter and a polarizer. The micro LED array includes a plurality of micro LEDs. The light transmission layer is located above the micro LED array. The color filter is located above the light transmission layer. The polarizer is located above the color filter.

In one example, the micro LED display device further includes an electrode layer, wherein the electrode layer drives the micro LED array to emit lights.

In one example, the micro LED display device further includes a first substrate and a second substrate, wherein the first substrate is located between the light transmission layer and the color filter, and the second substrate is located between the color filter and the polarizer.

In one example, the light transmission layer includes a quantum dot film, a polarizer film, a light enhancing film or a diffusion film.

In one example, the color filter includes a plurality of sub-pixel units; a color of each of the sub-pixel units is corresponded to a red color, a green color or a blue color.

In one example, a light color emitted from each of the micro LEDs includes a red light color, a green light color or a blue light color, and a color of each of the sub-pixel units is corresponded to the light color of each of the micro LEDs.

In one example, each of the micro LEDs emits a single light color.

In one example, each of the sub-pixel units of the color filter is departed by a mask.

In one example, each of the micro LEDs is aligned correspondingly to each of the sub-pixel units.

In one example, the sub-pixel units of the color filter are aligned in a linear shape, a square shape, a triangle shape or a mosaic shape.

### BRIEF DESCRIPTION OF THE DRAWINGS

The present disclosure can be more fully understood by reading the following detailed description of the embodiment, with reference made to the accompanying drawings as follows:

FIG. 1 is a schematic view showing a conventional LCD device;

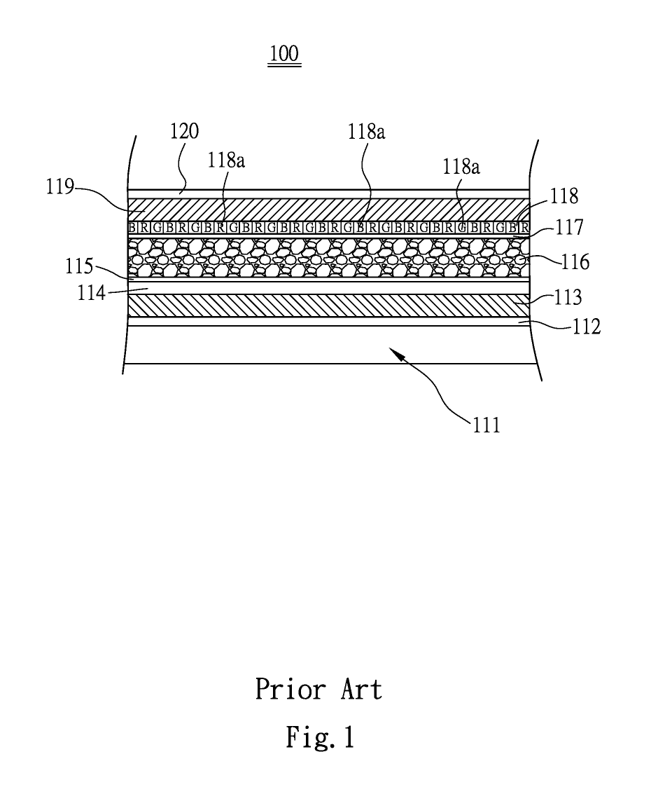

FIG. 2 is a schematic view showing a micro LED display device according to one embodiment of the present disclosure; and

FIG. 3 is a schematic view showing a micro LED display device according to another embodiment of the present disclosure.

### DETAILED DESCRIPTION

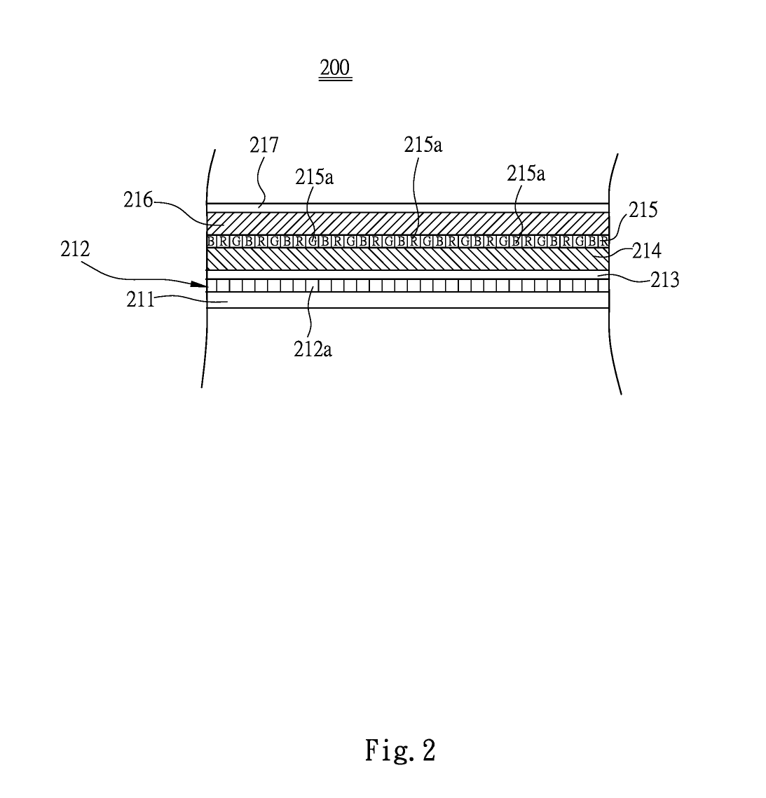

FIG. 2 is a schematic view showing a micro LED display device 200 according to one embodiment of the present disclosure. The micro LED display device 200 includes a micro LED array 212, a light transmission layer 213, a color filter 215 and a polarizer 217. In one example, the light transmission layer 213 is located above the micro LED array 212; the color filter 215 is located above the light transmission layer 213; and the polarizer 217 is located above the color filter 215. The micro LED display device 200 also includes a first substrate 214 and a second substrate 216. The first substrate 214 is located between the light transmission layer 213 and the color filter 215. The second substrate 216 is located between the color filter 215 and the polarizer 217. The micro LED display device 200 can further include an electrode layer 211. The electrode layer 211 can be located under the micro LED array 212 for electrically driving the micro LED array 212 to emit lights.

The operation mechanism of the micro LED display device 200 is then described. The micro LED array 212 includes a plurality of micro LEDs 212a which are aligned in order. Each of the micro LEDs 212a is electrically driven by the electrode layer 211, and can emit a light spontaneously. The electrode layer 211 can be made from conductive materials (metal or other materials), and can provide the required electric power. The lights emitted from the micro LED array 212 pass through the light transmission layer 213 located above. The micro LED 212a is commonly an inorganic LED, and the light emitted therefrom is commonly a point light source. Although the micro LEDs 212a can be aligned together to form an array to provide a large-area surface light source, however, controlling the alignment of the micro LEDs is still a challenge. In the present disclosure, the light transmission layer 213 can include a quantum dot film, a polarizer film, a light enhancing film, a diffusion film or a combination thereof. Therefore, a light shape of the light passed through the light transmission layer 213 can be enlarged for providing a uniformity surface light source.

For generating a color variation, the color filter 215 is disposed above the light transmission layer 213. It is known that an image is constructed by a plurality of pixels. The color filter 215 includes a plurality of sub-pixel units 215a. A single pixel can be formed by combining some of the sub-pixels 215a. For example, in a three primary color system, a sub-pixel unit 215a corresponded to a red color, a sub-pixel unit 215a corresponded to a green color and a sub-pixel unit 215a corresponded to a blue color are combined to form a single pixel. In a four primary color system, a sub-pixel unit 215a corresponded to a red color, a sub-pixel unit 215a corresponded to a green color, a sub-pixel unit 215a corresponded to a blue color and a sub-pixel unit 215a corresponded to a yellow color are combined to form a single pixel. In a six primary color system, a sub-pixel unit 215a corresponded to a red color, a sub-pixel unit 215a corresponded to a green color, a sub-pixel unit 215a corresponded to a blue color, a sub-pixel unit 215a corresponded to a cyan color, a sub-pixel unit 215a corresponded to a purple color and a sub-pixel unit 215a corresponded to a yellow color are combined to form a single pixel. A better color saturation and color reproduction can be achieved while using more sub-pixel units 215a with different colors. Furthermore, an alignment form of the sub-pixel units 215a also has influence on the color saturation. In other word, the sub-pixel units 215a of the color filter 215 can be aligned in a linear shape, a square shape, a triangle shape or a mosaic shape fir obtaining different color saturation.

A color variation is formed when a light passes through the color filter 215, and the micro LED array 212 is used to provide a required light source. The micro LED array 212 includes a plurality of micro LEDs 212a, and each of the micro LEDs 212a is aligned correspondingly to each of the sub-pixel units 215a of the color filter 215. Each of the micro LEDs 212a can emit the same or different light color. In one example, if the sub-pixel units 215a of the color filter 215 uses a three primary color system, a light color emitted from each of the micro LEDs includes a red light color, a green light color or a blue light color.

The polarizer 217 is used for generating a brightness variation (gray scale). A polarization angle and a polarization direction of a light can be adjusted when the light passes through the polarizer 217. Thus, the brightness variation (gray scale) can be adjusted for producing a colorful illumination as a natural light.

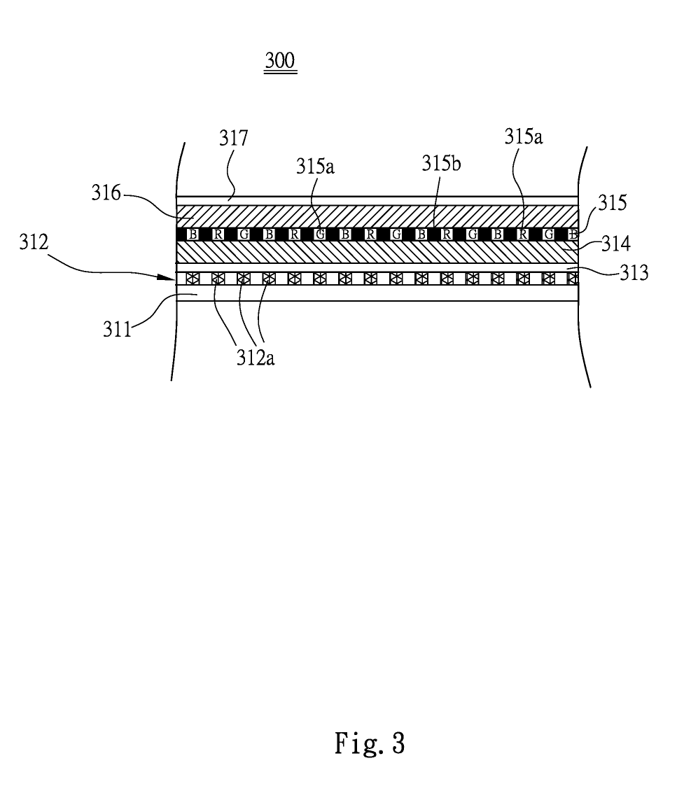

FIG. 3 is a schematic view showing a micro LED display device 300 according to another embodiment of the present disclosure. In FIG. 3, similar as the micro LED display device 200 in FIG. 2, the micro LED display device 300 includes an electrode layer 311, a micro LED array 312, a light transmission layer 313, a first substrate 314, a color filter 315, a second substrate 316 and a polarizer 317. The details of the functions and the alignment order of each layer are similar as that in FIG. 2, and are not addressed herein. The difference between the micro LED display device 200 and the micro LED display device 300 is that each of the sub-pixel units 315a in the micro LED display device 300 is departed by a mask 315b. The mask 315b can be used to block a scattered light for preventing the interference from the scattered light. The mask 315b can be made of black materials to form a so-call black matrix. Furthermore, each of the sub-pixel units 315b is aligned from each other, and each of the micro LEDs 312a is aligned correspondingly to each of the sub-pixel units 315b.

In the micro LED display device 200, 300, the emitted light is provided by the micro LED array 212, 312, and the micro LED array 212, 312 includes a plurality of micro LEDs 212a, 312a which are made of inorganic materials. The mechanism of color Illumination of such micro LED display device 200, 300 is significantly different from the conventional LCD device. Therefore, in the micro LED display device 200, 300 of the present disclosure, the backlight controlling structure can be simplified thereby reducing the manufacturing cost. Furthermore, the micro LED display device 200, 300 of the present disclosure has higher power efficiency, wider viewing angle and longer lifetime.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A micro LED display device, comprising:
a micro LED array comprising a plurality of micro LEDs;
a light transmission layer located above the micro led array;
a color filter located above the light transmission layer; and
a polarizer located above the color filter.

2. The micro LED display device of claim 1, further comprising:
an electrode layer, wherein the electrode layer drives the micro LED array to emit lights.

3. The micro LED display device of claim 1, further comprising:
a first substrate and a second substrate, wherein the first substrate is located between the light transmission layer and the color filter, and the second substrate is located between the color filter and the polarizer.

4. The micro LED display device of claim 1, wherein the light transmission layer comprises a quantum dot film, a polarizer film, a light enhancing film or a diffusion film.

5. The micro LED display device of claim 1, wherein the color filter comprises a plurality of sub-pixel units, a color of each of the sub-pixel units is corresponded to a red color, a green color or a blue color.

6. The micro LED display device of claim 1, wherein a light color emitted from each of the micro LEDs comprises a red light color, a green light color or a blue light color.

7. The micro LED display device of claim 6, wherein a color of each of the sub-pixel units is corresponded to the light color of each of the micro LEDs.

8. The micro LED display device of claim 5, wherein each of the micro LEDs emits a single light color.

9. The micro LED display device of claim 1, wherein each of the sub-pixel units of the color filter is departed by a mask.

10. The micro LED display device of claim 1, wherein each of the micro LEDs is aligned correspondingly to each of the sub-pixel units.

11. The micro LED display device of claim 1, wherein the sub-pixel units of the color filter are aligned in a linear shape, a square shape, a triangle shape or a mosaic shape.
